(19) United States
(12) Patent Application Publication
(10) Pub. No.: US 2025/0133752 A1
(43) Pub. Date: Apr. 24, 2025

(54) STACK TYPE SEMICONDUCTOR MEMORY DEVICE

(71) Applicant: SK hynix Inc., Icheon-si (KR)

(72) Inventor: Hee Sun LEE, Icheon-si (KR)

(21) Appl. No.: 18/424,688

(22) Filed: Jan. 26, 2024

(30) Foreign Application Priority Data
Oct. 23, 2023 (KR) 10-2023-0142090

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436

(57) ABSTRACT

A stack type semiconductor device includes a first semiconductor structure having a first integrated circuit layer and a first bonding layer and a second semiconductor structure having a second integrated circuit layer and a second bonding layer. The first integrated circuit layer has a first thermal endurance on one surface of the first integrated circuit layer. The first bonding layer is formed on the first integrated circuit layer. The second integrated circuit layer has a second thermal endurance, lower than the first thermal endurance, on one surface of the second integrated circuit layer. The second bonding layer is formed on the second integrated circuit layer and is hybrid-bonded to the first bonding layer. A third thermal endurance lower than the first thermal endurance. The third integrated circuit is arranged to face at least one of the first integrated circuit layer and the second integrated circuit layer.

### CROSS-REFERENCES TO RELATED APPLICATION

The present application claims priority under 35 U.S.C. § 119(a) to Korean application number 10-2023-0142090, filed on Oct. 23, 2023, in the Korean Intellectual Property Office, which is incorporated herein by reference in its entirety.

### BACKGROUND

### 1. Technical Field

Various embodiments generally relate to a semiconductor integrated circuit device, more particularly, to a stack type semiconductor memory device and a method of manufacturing the stack type semiconductor memory device.

### 2. Related Art

In order to satisfy good performance and low cost required by customers, a degree of integration of semiconductor devices should be increased.

The degree of integration of the semiconductor device may be an important factor for determining a price of an electronic part. Thus, a degree of integration of a two-dimensional or a planar semiconductor device may be determined in accordance with an occupying area of a unit memory cell.

Particularly, because a fine pattern to increase the degree of integration may require an expensive exposure equipment or an exposure apparatus having a high resolution, there may exist a limit of the increasing of the degree of integration in the two-dimensional semiconductor device.

Recently, in order to secure a higher degree of integration of semiconductor devices, particularly, a semiconductor memory device, the memory cells may be stacked in a three-dimension or a technology for stacking a memory cell array and a peripheral circuit in a vertical direction may be proposed.

The stack type semiconductor device may include layers having elements formed by various processes so that maintenance of electrical properties between the elements may determine a performance of the stack type semiconductor device.

### SUMMARY

Example embodiments provide a stack type semiconductor device that may be capable of securing electrical reliability.

Example embodiments also provide a method of manufacturing the above-mentioned stack type semiconductor device.

According to example embodiments, there may be provided a stack type semiconductor device. The stack type semiconductor device may include a first semiconductor structure and a second semiconductor structure hybrid-bonded to each other. The first semiconductor structure may include a first integrated circuit layer and a first bonding layer. The first integrated circuit layer may have a first thermal endurance on one surface of the first integrated circuit layer. The first bonding layer may be formed over the first integrated circuit layer. The second semiconductor structure may include a second integrated circuit layer and a second bonding layer. The second integrated circuit layer may have a second thermal endurance, which may be lower than the first thermal endurance, on one surface of the second integrated circuit layer. The second bonding layer may be formed on the second integrated circuit layer. The second bonding layer may be hybrid-bonded to the first bonding layer. A third thermal endurance, which may be lower than the first thermal endurance. The third integrated circuit layer is arranged to face at least one of the first integrated circuit layer and the second integrated circuit layer.

In example embodiments, the third thermal endurance may be substantially equal to or lower than the second thermal endurance.

In example embodiments, the first semiconductor structure may further include at least one penetration electrode formed through the first integrated circuit layer and the third integrated circuit layer.

In example embodiments, the first integrated circuit layer may include at least one capacitor. The capacitor may include a storage electrode, a dielectric layer and a plate electrode sequentially stacked.

In example embodiments, the second integrated circuit layer may include a plurality of transistors and a plurality of interconnections connected between the transistors.

In example embodiments, the third integrated circuit layer may include at least one analog element dependent upon a temperature.

In example embodiments, the first bonding layer may include a plurality of first bonding pads electrically connected with the first integrated circuit layer. The second bonding layer may include a plurality of second bonding pads electrically connected with the second integrated circuit layer. The second bonding pads may be hybrid-bonded to the first bonding pads.

In example embodiments, the second thermal endurance may be a thermal expansion temperature of the first bonding pads and the second bonding pads.

According to example embodiments, there may be provided a stack type semiconductor device. The stack type semiconductor device may include a first semiconductor structure and a second semiconductor structure. The first semiconductor structure may include a first surface and a second surface opposite to the first surface. The first semiconductor structure may include at least one memory component integrated on the first surface and a logic circuit layer integrated on the second surface. The second semiconductor structure may include a third surface and a fourth surface opposite to the third surface. The second semiconductor structure may include a control circuit layer integrated on the third surface to control the memory component. The first semiconductor structure and the second semiconductor structure may be hybrid-bonded to each other to face the memory component and the control circuit layer.

According to example embodiments, there may be provided a method of manufacturing a stack type semiconductor device. In the method of manufacturing the stack type semiconductor device, a first integrated circuit layer may be formed on a first surface of a first semiconductor substrate at a first temperature. A first bonding layer may be formed on the first integrated circuit layer. The first bonding layer may include a plurality of first bonding pads electrically connected with the first integrated circuit layer and a first bonding insulation layer configured to electrically isolate the first bonding pads from each other. A second integrated circuit layer may be formed on a second semiconductor substrate. A second bonding layer may be formed on the second integrated circuit layer. The second bonding layer may include a plurality of second bonding pads electrically connected with the second integrated circuit layer and a second bonding insulation layer configured to electrically isolate the second bonding pads from each other. The first bonding layer and the second bonding layer may be hybrid-bonded to each other at a second temperature lower than the first temperature. A third integrated circuit layer may be formed on the second surface of the first semiconductor substrate, which may not be bonded to the second semiconductor substrate, at a third temperature lower than the first temperature.

According to example embodiments, the memory layer formed by a high temperature process and the control circuit layer formed by a low temperature process may be formed at different substrates to prevent characteristics of the control circuit layer from being changed by a high temperature.

Further, after the first semiconductor substrate with the memory layer is be bonded to the second semiconductor substrate with the control circuit layer, the logic circuit layer formed at a low temperature may be additionally formed on a backside of the first semiconductor substrate. Thus, a thermal burden applied to the control circuit layer and the logic circuit layer may be reduced to improve characteristics of the stack type semiconductor device.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a cross-sectional view illustrating a stack type semiconductor device in accordance with an embodiment of the disclosure;

FIGS. 2 to 6 are cross-sectional views illustrating a method of manufacturing a stack type semiconductor device in accordance with an embodiment of the disclosure; and

FIG. 7 is a flow chart illustrating a method of manufacturing a stack type semiconductor device in accordance with an embodiment of the disclosure.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure is described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the phrase “coupled to” and “connected to” refer to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

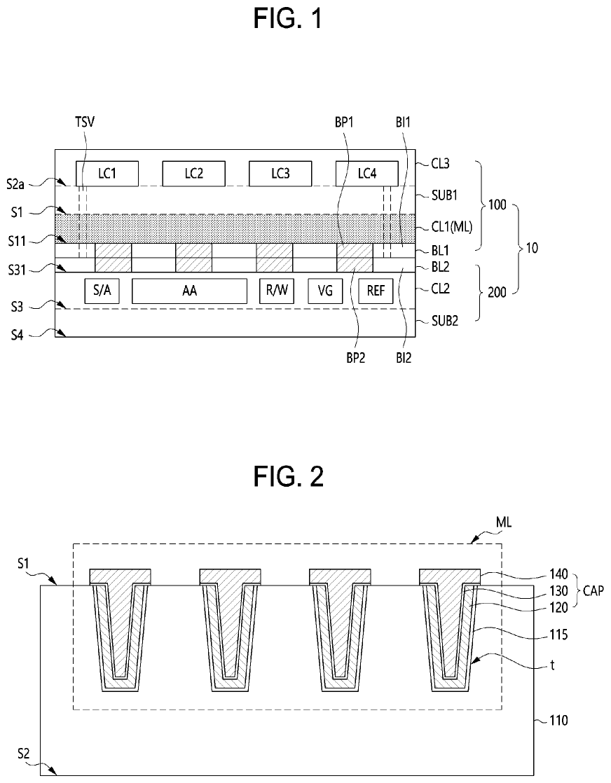

FIG. 1 is a cross-sectional view illustrating a stack type semiconductor device in accordance with an embodiment of the disclosure.

Referring to FIG. 1, a stack type semiconductor device 10 may include a first semiconductor structure 100 and a second semiconductor structure 200 hybrid-bonded to each other in a three-dimensional shape.

At least one of the first semiconductor structure 100 and the second semiconductor structure 200 may include a semiconductor wafer or a semiconductor chip. In an embodiment of the disclosure, all the first semiconductor structure 100 and the second semiconductor structure 200 may include the semiconductor wafer. Alternatively, all the first semiconductor structure 100 and the second semiconductor structure 200 may include the semiconductor chip. Further, the stack type semiconductor device 10 of an embodiment of the disclosure may be a part of a semiconductor package.

The first semiconductor structure 100 may include a first semiconductor substrate SUB1. The first semiconductor substrate SUB1 may have a first surface S1 and a second surface S2a opposite to the first surface S1. The first semiconductor substrate SUB1 may include a silicon substrate, a single crystalline silicon substrate, an epitaxial semiconductor substrate, a silicon germanium substrate, etc. Further, the first semiconductor substrate SUB1 may include, for example, an intrinsic semiconductor material, conductive impurities, etc.

In an embodiment of the disclosure, the first surface S1 may be a front surface, a top surface, an upper surface or one surface of the first semiconductor substrate SUB1. The second surface S2a may be a rear surface, a bottom surface, a lower surface or the other surface of the first semiconductor substrate SUB1. Alternatively, the first surface S1 may be the rear surface, the bottom surface, the lower surface or the other surface of the first semiconductor substrate SUB1. The second surface S2a may be the front surface, the top surface, the upper surface or the one surface of the first semiconductor substrate SUB1.

The first semiconductor structure 100 may include a first integrated circuit layer CL1 formed on the first surface S1.

The first integrated circuit layer CL1 may include a memory layer ML. The memory layer ML may include a plurality of memory components formed at a first temperature, for example, at a high temperature of about 400° C. to about 700° C. For example, the memory component may include a plurality of capacitors. The capacitors may be arranged in a memory cell array. The capacitors may be electrically isolated from each other. Further, the memory components may be integrated on the first surface S1 of the first semiconductor substrate SUB1 by a front end of line (FEOL). The FEOL may include a process for forming elements or components on a semiconductor substrate by a deposition process and a patterning process.

The first semiconductor structure 100 may include a first bonding layer BL1. The first bonding layer BL1 may be formed on a surface S11 of the memory layer ML corresponding to the first integrated circuit layer CL1. In an embodiment of the disclosure, the first bonding layer BL1 may include a plurality of first bonding pads BP1 and a first bonding insulation layer Bl1. The first bonding pads BP1 may be electrically connected with the memory components of the memory layer ML. For example, conductive components in the memory layer ML may be connected with the first bonding pads BP1 through at least one interconnection. The first bonding insulation layer Bl1 may be positioned between the first bonding pads BP1 to electrically isolate the first bonding pads BP1 from each other.

The second semiconductor structure 200 may include a second semiconductor substrate SUB2. The second semiconductor substrate SUB2 may have a third surface S3 and a fourth surface S4 opposite to the third surface S3. The second semiconductor substrate SUB2 may include, for example, a single crystalline silicon substrate, an epitaxial semiconductor substrate, a silicon germanium substrate, a polysilicon layer, a supporting layer including a semiconductor material, a silicon on insulator (SOI) substrate, etc., but not limited thereto.

In an embodiment of the disclosure, the third surface S3 may be a front surface, a top surface, an upper surface or one surface of the second semiconductor substrate SUB2. The fourth surface S4 may be a rear surface, a bottom surface, lower surface or the other surface of the second semiconductor substrate SUB2. Alternatively, the third surface S3 may be the rear surface, the bottom surface, the lower surface or the other side surface of the second semiconductor substrate SUB2. The fourth surface S4 may be the front surface, the top surface, the upper surface or the one surface of the second semiconductor substrate SUB2.

In an embodiment of the disclosure, the second semiconductor structure 200 may include a second integrated circuit layer CL2 formed on the third surface S3. The second integrated circuit layer CL2 may include a plurality of transistors and a plurality of interconnections. The transistors and the interconnections of the second integrated circuit layer CL2 may form various control circuits. The control circuit may selectively input/output data into/from the memory components of the first semiconductor structure 100.

For example, the second integrated circuit layer CL2 may include a plurality of access transistors AA. The access transistors AA may be connected to the memory components of the first semiconductor structure 100, for example, the capacitors. The access transistors AA may be arranged in an array together with the capacitors to form a stack type memory cell array.

Further, the second integrated circuit layer CL2 may include a sense amplifier S/A configured to sense data in the memory components. The second integrated circuit layer CL2 may further include a read/write circuit R/W configured to read or write the data in or from the memory components, and a voltage generation circuit VG configured to generate a read voltage, a write voltage and an operation voltage. The second integrated circuit layer CL2 may include a refresh circuit REF configured to prevent a leakage current of the memory components, i.e., the capacitors. Although not illustrated in the drawings, the second integrated circuit layer CL2 may include a plurality of word lines and a plurality of bit lines. The second integrated circuit layer CL2 may include a word line decoder configured to select any one among the plurality of word lines and a bit line decoder configured to select any one among the plurality of bit lines.

The transistors in the second integrated circuit layer CL2 may be formed by the FEOL, but not limited thereto.

The second semiconductor structure 200 may include a second bonding layer BL2. The second bonding layer BL2 may be bonded to the first bonding layer BL1 of the first semiconductor structure 100. The second bonding layer BL2 may be formed on a surface S31 of the second integrated circuit layer CL2. In an embodiment of the disclosure, the second bonding layer BL2 may include a plurality of second bonding pads BP2 and a second bonding insulation layer BI2.

The second bonding pads BP2 may be electrically connected with the conductive components of the second integrated circuit layer CL2. The second bonding insulation layer BI2 may be positioned between the second bonding pads BP2 to electrically isolate the second bonding pads BP2 from each other.

The second bonding pads BP2 may be hybrid-bonded to the first bonding pads BP1. The second bonding insulation layer BI2 may be hybrid-bonded to the first bonding insulation layer Bl1. In an embodiment of the disclosure, the hybrid bonding may be referred to as a fusion bonding or a direct bonding. For example, the first bonding insulation layer Bl1 and the second bonding insulation layer BI2 may be bonded to each other by a compression process. The first bonding pads BP1 and the second bonding pads BP2 may be bonded to each other by thermal expansions in an annealing process. The annealing process may be performed at a second temperature lower than the first temperature. For example, the second temperature may be about 100° C. to about 300° C. The second temperature may correspond to a hybrid bonding temperature.

Performances and electrical characteristics/properties of the transistors and the interconnections in the second integrated circuit layer CL2 may be guaranteed until the second temperature. The guarantee of the performances or a maintenance of the electrical characteristics or properties may mean that a threshold voltage, an output current, a wiring resistance, an operation speed, etc., of a MOS transistor may be maintained within an error range. The second temperature may be a thermal endurance of the second integrated circuit layer CL2.

The first semiconductor structure 100 may further include a third integrated circuit layer CL3 on the second surface S2a non-bonded to the second semiconductor structure 200.

The third integrated circuit layer CL3 may include a plurality of conductive patterns. The conductive patterns may include a logic circuit. The logic circuit may, for example, include an arithmetic and logic calculation circuit LC1 of data in the memory components, a data pipeline operation circuit LC2, an interface circuit LC3 for receiving and process an external signal and analog elements LC4.

The third integrated circuit layer CL3 may include elements or components dependent upon a temperature. For example, a performance or characteristics of the third integrated circuit layer CL3 may be guaranteed to a third temperature lower than the first temperature. The third temperature may be substantially equal to or lower than the second temperature. For example, the third temperature may be a room temperature to about 250° C.

In an embodiment of the disclosure, although not illustrated in the drawings, the third integrated circuit layer CL3 may be formed on the fourth surface S4 of the second semiconductor substrate SUB2. The third integrated circuit layer CL3 may be connected with the second integrated circuit layer CL2 via a penetration electrode.

In an embodiment of the disclosure, the first semiconductor structure 100 may include at least one penetration electrode TSV formed through the first semiconductor substrate SUB1. The penetration electrode TSV may be electrically connected between the memory components of the memory layer ML and the conductive patterns of the third integrated circuit layer CL3.

According to an embodiment of the disclosure, after the integrated circuit layers CL1, CL2, CL3 having the different thermal endurances may be divided into each other, the integrated circuit layers CL1, CL2, CL3 may be sequentially formed in an order from a high thermal endurance to a low thermal endurance to secure the electrical reliability of the stack type semiconductor device 10.

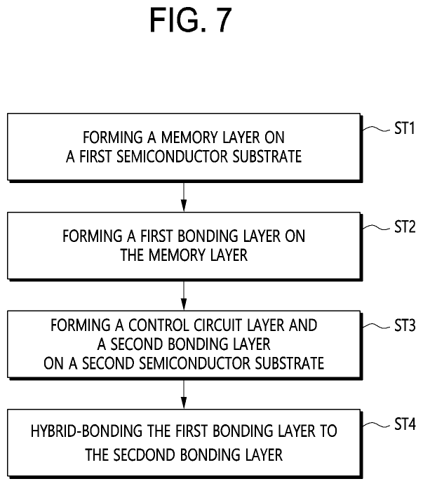

FIGS. 2 to 6 are cross-sectional views illustrating a method of manufacturing a stack type semiconductor device in accordance with an embodiment of the disclosure and FIG. 7 is a flow chart illustrating a method of manufacturing a stack type semiconductor device in accordance with an embodiment of the disclosure.

Referring to FIGS. 2 and 7, in step ST1, the memory layer ML corresponding to the first integrated circuit layer may be formed on the first surface S1 of the first semiconductor substrate 110. The first semiconductor substrate 110 may include, for example, the silicon substrate, the single crystalline silicon substrate, the epitaxial semiconductor substrate, the silicon germanium substrate, etc.

The first surface S1 of the first semiconductor substrate 110 may be etched to form trenches t. The trenches t may be arranged in a uniform rule. The uniform rule may correspond to an arrangement of a memory cell array.

A sidewall protection layer 115 may be formed on inner walls of the trenches t. The sidewall protection layer 115 may include an insulation material.

A conductive layer having a conformal thickness may be formed on the first surface S1 of the first semiconductor substrate 110. The conductive layer may be planarized to form a storage electrode 120 in the trench t. In an embodiment of the disclosure, the conductive layer may include iridium (Ir), ruthenium (Ru), platinum (Pt), or a novel metal having a work function. Further, the conductive layer may include a metal nitride layer such as a titanium nitride layer. The storage electrode 120 and the first semiconductor substrate 110 may be electrically isolated from each other by the sidewall protection layer 115.

A dielectric layer 130 may be formed on the storage electrode 120. The dielectric layer 130 may include a meal oxide layer having a high dielectric constant such as HfO₂, doped HfO₂, HfZrO, doped HfZrO, Ta₂O₅, ZrO₂, Al₂O₅, TiO₂, etc. In order to secure a high capacitance, a high crystallizing process may be performed on the dielectric layer 130 at a temperature of about 400° C. to about 700° C. Because the first semiconductor substrate 110 may not include other transistors except for the storage electrode 120, other electrical characteristics may not be changed by the high crystallizing process.

A conductive layer may be formed on the dielectric layer 130. The conductive layer may include a material substantially equal to or different from the storage electrode 120. The trench t may be fully filled with the conductive layer. The conductive layer and the dielectric layer 130 may be patterned to place the conductive layer on the trench t, thereby forming a plate electrode 140. Thus, a capacitor CAP including the storage electrode 120, the dielectric layer 130, and the plate electrode 140 may be formed in the trench t.

The storage electrode 120, the dielectric layer 130, and the plate electrode 140 may be formed by various processes to provide the capacitor CAP with various structures.

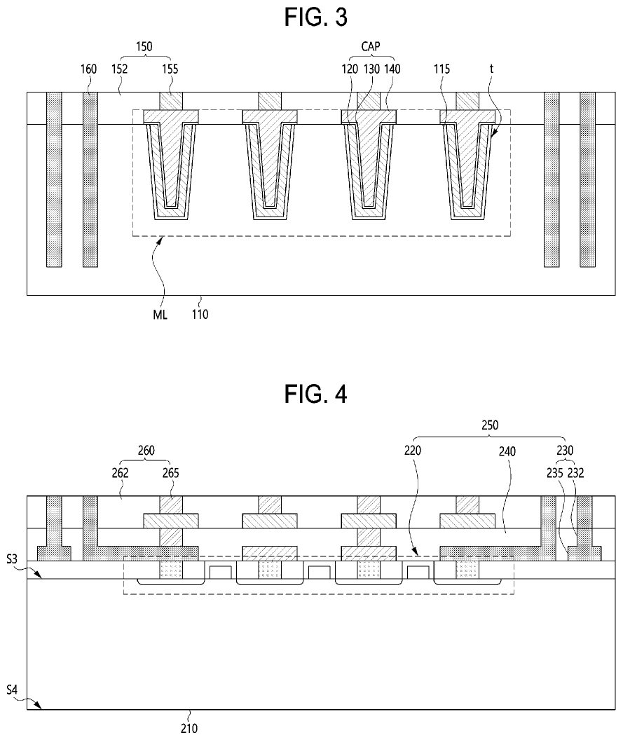

Referring to FIGS. 3 and 7, in step ST2, the first bonding layer 150 may be formed on the memory layer ML of the first semiconductor substrate 110.

In an embodiment of the disclosure, the first bonding insulation layer 152 may be formed on the first semiconductor substrate 110 with the memory layer ML. The first bonding insulation layer 152 may include at least one insulation layer. For example, the first bonding insulation layer 152 may include a silicon oxide layer. The first bonding insulation layer 152 may be etched to form pad regions. The pad regions may be filled with a conductive material to form first bonding pads 155. The conductive material may, for example, include copper, but not limited thereto.

In an embodiment of the disclosure, a part of the first bonding pads 155 may be electrically connected to the plate electrode 140 of the capacitor CAP. Further, although not illustrated in the drawings, another part of the first bonding pads 155 may be electrically connected to the storage electrode 120 of the capacitor CAP.

In an embodiment of the disclosure, a plurality of the penetration electrodes 160 may be formed through the first bonding layer 150 and the first semiconductor substrate 110. For example, the penetration electrode 160 may be extended from a surface of the first bonding layer 150 to the first semiconductor substrate 110 by a set depth. The set depth may be less than a length between the surface of the first bonding layer 150 and a second surface S2 of the first semiconductor substrate 110.

In an embodiment of the disclosure, in forming the penetration electrode 160, the first bonding layer 150 and the first semiconductor substrate 110 may be etched by the set depth to form a deep trench. An insulation layer may be formed on a sidewall of the deep trench. The deep trench may be filled with a conductive material. The first semiconductor substrate 110 and the penetration electrode 160 may be electrically isolated from each other by the insulation layer on the sidewall of the deep trench.

Alternatively, the penetration electrode 160 may be formed before forming the capacitor CAP. The penetration electrode 160 formed before forming the capacitor CAP may be directly connected to the storage electrode 120.

Referring to FIGS. 4 and 7, the control circuit layer 250 and the second bonding layer 260, which may correspond to the second integrated circuit layer CL2, may be formed on the second semiconductor substrate 210.

The second semiconductor substrate 210 may have the third surface S3 and the fourth surface S4 opposite to the third surface S3. The second semiconductor substrate 210 may include a single crystalline silicon substrate, an epitaxial silicon substrate, a silicon germanium substrate, a polysilicon layer, a supporting plate including a semiconductor material, an SOI substrate, etc. The second semiconductor substrate 210 may be substantially equal to or different from the first semiconductor substrate 110. Further, the third surface S3 of the second semiconductor substrate 210 may be an upper surface of the second semiconductor substrate 210, but not limited thereto. The fourth surface S4 may be a lower surface of the second semiconductor substrate 210, but not limited thereto.

The control circuit layer 250 may be integrated on the third surface S3 of the second semiconductor substrate 210. The control circuit layer 250 may include the transistors 220 formed by the FEOL. The control circuit layer 250 may include the interconnections 230 electrically connected to the transistors 220.

In an embodiment of the disclosure, the transistors 220 may have at least one of a horizontal channel structure and a vertical channel structure. The horizontal channel may be parallel to the surface of the second semiconductor substrate 210. The vertical channel may be extended in a direction substantially perpendicular to the surface of the second semiconductor substrate 210.

A part of the transistors 220 may be operated as an access transistor of the memory cell array. For example, the access transistor may be integrated in a position corresponding to the memory cell region of the memory cell array. Another part of the transistors 220 may form the sense amplifier electrically connected with the access transistor. Another part of the transistors 220 may form a memory peripheral circuit directly and indirectly connected to the access transistor. The memory peripheral circuit may include a read/write circuit, a refresh circuit and a voltage generation circuit.

The interconnections 230 may be directly and indirectly connected to the transistors 220. The interconnections 230 may include a plurality of vertical connections 232 and a plurality of horizontal connections 235. The vertical connections 232 may correspond to a contact plug or a via plug. The horizontal connections 235 may include a conductive wiring.

A part of the interconnections 230 may be operated as a middle connection medium connected between the access transistor and the capacitor CAP in the first semiconductor substrate 110. A part of the interconnections 230 may be connected between the transistors 220 to form the sense amplifier. Further, the part of the interconnections 230 may be connected between the access transistor and the sense amplifier. A part of the interconnections 230 may be connected between the transistors 220 to form the memory peripheral circuit such as the read/write circuit, the voltage generation circuit, the refresh circuit, the decoding circuit, etc. A part of the interconnections 230 may be connected between the memory peripheral circuit and the access transistor, or between the memory peripheral circuit and an external terminal.

The control circuit layer 250 may further include at least one insulating interlayer 240 interposed between the transistors 220 and the interconnections 230, and between the interconnections 230. For example, the vertical connection 232 of the interconnection 230 may be formed through the at least one layer of the insulating interlayer 240. The horizontal connection 235 may be placed on a lower surface or an upper surface of the insulating interlayer 240.

In an embodiment of the disclosure, the transistors 220 and the interconnections 230 may be formed by various processes.

The second bonding insulation layer 262 may be formed on the second semiconductor substrate 210 with the control circuit layer 250. The second bonding insulation layer 262 may include at least one insulation layer. The second bonding insulation layer 262 may include a silicon oxide layer. The second bonding insulation layer 262 may be etched to form pad regions. The pad regions may be filled with a conductive material to form the second bonding pads 265. The second bonding pads 265 may be electrically connected to the interconnections 230.

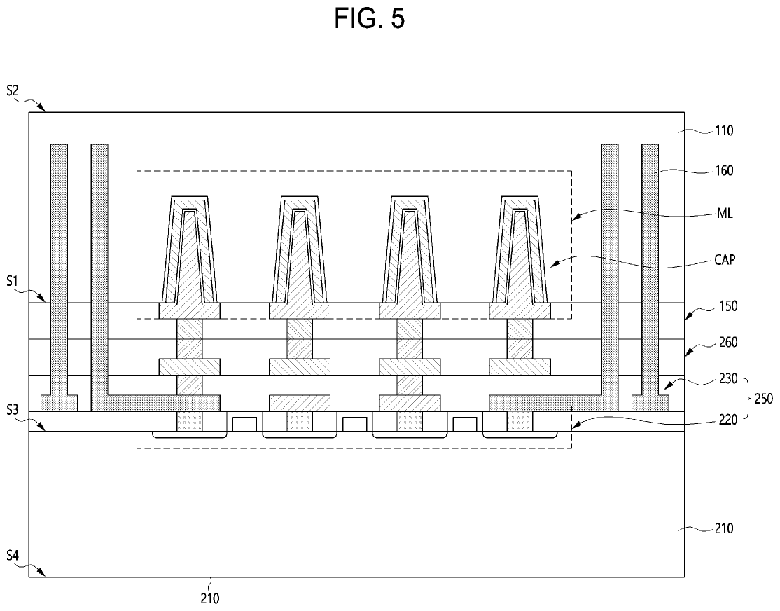

Referring to FIGS. 5 and 7, in step ST4, the first bonding layer 150 of the first semiconductor substrate 110 may be hybrid-bonded to the second bonding layer 260 of the second semiconductor substrate 210.

For example, the first semiconductor substrate 110 may be flipped to face the first bonding layer 150 and the second bonding layer 260. The first bonding pad 155 of the first bonding layer 150 and the second bonding pad 265 of the second bonding layer 260, which may receive a same signal, may be aligned with each other to perform the hybrid-bonding process.

In an embodiment of the disclosure, the first bonding insulation layer 152 and the second bonding insulation layer 262 may be preliminarily bonded to each other by a compression process. An annealing process may be performed so that the first bonding pad 155 and the second bonding pad 265 may be thermally expanded to thermally and chemically bond the first bonding pad 155 and the second bonding pad 265 to each other. The annealing process may be performed at a temperature of about 100° C. to about 300° C. The thermal endurance of the transistors 220 and the conductive patterns in the control circuit layer 250 may be the temperature of the annealing process.

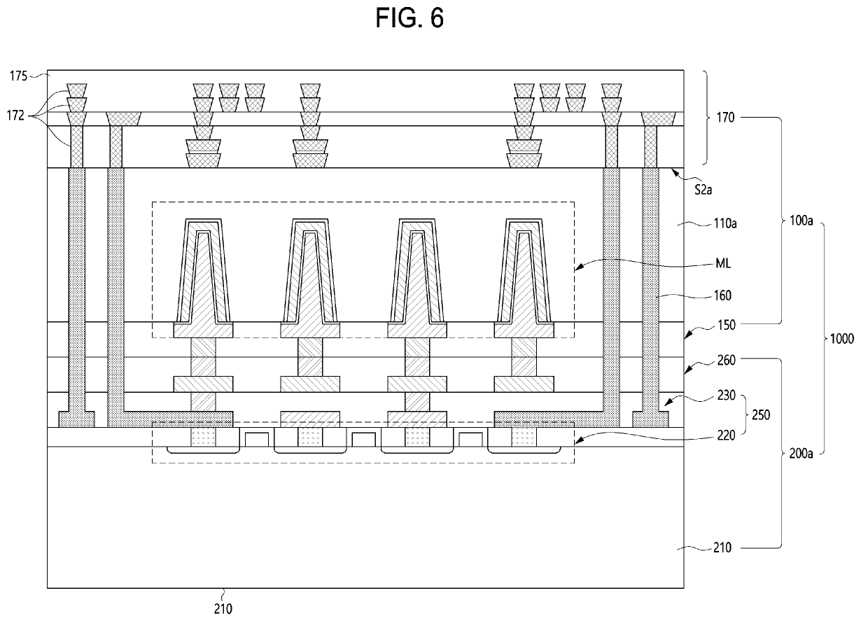

Referring to FIGS. 6 and 7, in an embodiment of the disclosure, a second surface S2 of the first semiconductor substrate 210, which may not be bonded to the second semiconductor substrate 210, may be grinded until the penetration electrode 160 may be exposed. The reference numeral S2a may correspond to the second surface of the thin first semiconductor substrate 110.

A logic circuit layer 170 may be formed on the second surface S2a. The logic circuit layer 170 may include a plurality of conductive patterns 172 and a plurality of insulating interlayers 175. The conductive patterns 172 may be positioned on the same plane. Alternatively, the conductive patterns 172 may be stacked to be positioned on different planes. The conductive patterns 172 on the same plane and the different planes may be electrically isolated from each other by the insulating interlayers 175.

Part of the conductive patterns 172 may form the arithmetic and logic circuit for calculating the data in the capacitor CAP. Part of the conductive patterns 172 may form the data pipeline operation circuit and the interface circuit. Part of the conductive patterns 172 may form the analog elements such as the resistance and the capacitor CAP. The logic circuit layer 170, particularly the analog elements, may be dependent upon the temperature. Thus, it may be required to form the logic circuit layer 170 at the third temperature lower than the first temperature, for example, from room temperature to about 250° C. The logic circuit layer 170 may additionally be formed after the process for forming the capacitor CAP at the high temperature such as the first temperature, and the hybrid-bonding process at the middle temperature such as the second temperature. Thus, the logic circuit layer 170 may be formed without the thermal burden.

Further, because the logic circuit layer 170 may additionally be formed at the low temperature such as the third temperature, the bonding characteristics between the first and second bonding layers 150 and 260 as well as the electrical characteristics of the memory layer ML and the control circuit layer 250 may be maintained.

Therefore, a stack type semiconductor device 1000 may be completed. The stack type semiconductor device 1000 may include the first semiconductor structure 100a and the second semiconductor structure 200a. The first semiconductor structure 100a may include the memory layer ML and the logic circuit layer 170 with the different thermal endurances. The second semiconductor structure 200a may include the control circuit layer 250.

According to an embodiment of the disclosure, the memory layer ML formed by a high temperature process and the control circuit layer 250 formed by a low temperature process may be formed at different substrates to prevent characteristics of the control circuit layer 250 from being changed by a high temperature.

Further, after the first semiconductor substrate 110a with the memory layer ML may be bonded to the second semiconductor substrate 210 with the control circuit layer 250, the logic circuit layer 170 formed at a low temperature may be additionally formed on the other side of the first semiconductor substrate 110a. Thus, a thermal burden applied to the control circuit layer 250 and the logic circuit layer 170 may be reduced to improve characteristics of the stack type semiconductor device 1000.

The above described embodiments of the present disclosure are intended to illustrate and not to limit the present disclosure. Various alternatives and equivalents are possible. The disclosure is not limited by the embodiments described herein. Nor is the disclosure limited to any specific type of semiconductor device. Another additions, subtractions, or modifications are obvious in view of the present disclosure and are intended to fall within the scope of the appended claims.

What is claimed is:

1. A stack type semiconductor device comprising:
a first semiconductor structure including a first integrated circuit layer and a first bonding layer, the first bonding layer formed over the first integrated circuit layer having a first thermal endurance; and
a second semiconductor structure including a second integrated circuit layer and a second bonding layer, the second bonding layer formed over the second integrated circuit layer having a second thermal endurance lower than the first thermal endurance, and the second bonding layer hybrid-bonded to the first bonding layer,
wherein a third integrated circuit layer is integrated on at least one of the first semiconductor structure and the second semiconductor structure, and
wherein the third integrated circuit layer has a third thermal endurance lower than the first thermal endurance, and the third integrated circuit layer is arranged to face at least one of the first integrated circuit layer and the second integrated circuit layer.

2. The stack type semiconductor device of claim 1, wherein the third thermal endurance is substantially equal to or lower than the second thermal endurance.

3. The stack type semiconductor device of claim 2, wherein the first semiconductor structure further comprises at least one penetration electrode configured to electrically connect the first integrated circuit layer with the third integrated circuit layer.

4. The stack type semiconductor device of claim 1, wherein the first integrated circuit layer comprises at least one capacitor comprising a storage electrode, a dielectric layer and a plate electrode that are sequentially stacked, and the first thermal endurance is a crystallized temperature of the dielectric layer.

5. The stack type semiconductor device of claim 1, wherein the second integrated circuit layer comprises a plurality of transistors and a plurality of interconnections connected between the plurality of transistors.

6. The stack type semiconductor device of claim 1, wherein the third integrated circuit layer comprises at least one analog element.

7. The stack type semiconductor device of claim 1, wherein the first bonding layer comprises a plurality of first bonding pads electrically connected to the first integrated circuit layer, the second bonding layer comprises a plurality of second bonding pads electrically connected to the second integrated circuit layer and hybrid-bonded to the plurality of first bonding pads, and the second thermal endurance is a thermal expansion temperature of the plurality of first bonding pads and the plurality of second bonding pads.

8. The stack type semiconductor device of claim 1, wherein the first semiconductor structure includes a first substrate which has a first surface on which the first integrated circuit layer and the first bonding layer are formed, and a second surface opposite to the first surface,
wherein the second semiconductor structure includes a second substrate which has a third surface on which the second integrated circuit layer and the second bonding layer are formed, and a fourth surface opposite to the second surface, and
wherein the third integrated circuit layer is integrated on at least one of the second surface of the first substrate and the fourth surface of the second substrate.

9. A stack type semiconductor device comprising:
a first semiconductor structure having a first surface and a second surface opposite to the first surface, the first semiconductor structure including at least one memory component on the first surface and a logic circuit layer on the second surface; and
a second semiconductor structure having a third surface and a fourth surface opposite to the third surface, the second semiconductor structure including a control circuit layer integrated on the third surface to control the at least one memory component,
wherein the first semiconductor structure and the second semiconductor structure are hybrid-bonded to face the at least one memory component and the control circuit layer.

10. The stack type semiconductor device of claim 9, wherein the at least one memory component comprises a plurality of capacitors, and the control circuit layer comprises a plurality of access transistors configured to selectively transmit data to the plurality of capacitors.

11. The stack type semiconductor device of claim 9,
wherein the first semiconductor structure further comprises a first bonding layer positioned on the at least one memory component and hybrid-bonded to the second semiconductor structure, and
wherein the first bonding layer comprises:
a plurality of first bonding pads electrically connected to the at least one memory component; and
a first bonding insulation layer configured to electrically isolate the plurality of first bonding pads from each other.

12. The stack type semiconductor device of claim 11,
wherein the second semiconductor structure further comprises a second bonding layer positioned on the control circuit layer, and
wherein the second bonding layer comprises:
a plurality of second bonding pads electrically connected to the control circuit layer and bonded to the plurality of first bonding pads; and
a second bonding insulation layer configured to electrically isolate the plurality of second bonding pads from each other.

13. The stack type semiconductor device of claim 10, wherein the logic circuit layer comprises at least one of an arithmetic and logic circuit for calculating data in the at least one memory component, a data pipeline circuit, an interface circuit for receiving and processing an external signal, and at least one analog element.
